(19) United States
(12) Patent Application Publication
(10) Pub. No.: US 2005/0199969 A1
(43) Pub. Date: Sep. 15, 2005

(54) Pressure sensor

(76) Inventors: Chiaki Kobayashi, Tottori-Shi (JP); Daisuke Sumi, Tottori-Shi (JP); Hiroshi Inamura, Tottori (JP); Togo Morifumi, Tottori (JP); Koji Yoshida, Tottori (JP); Masaki Endo, Tottori (JP); Sayaka Hiura, Tottori-Shi (JP); Takao Yamauchi, Tottori-Shi (JP)

Correspondence Address: ARENT FOX PLLC, 1050 CONNECTICUT AVENUE, N.W., SUITE 400, WASHINGTON, DC, 20036, US

(21) Appl. No.: 10/507,366

(22) PCT Filed: Mar. 27, 2003
(86) PCT No.: PCT/JP03/03900

§ 371 Date: May 18, 2005

(30) Foreign Application Priority Data
Mar. 29, 2002 (JP) 2002-094972

(51) Int. Cl. H01L 27/14

(52) U.S. Cl. 257/414

(57) ABSTRACT

A pressure sensor comprising a plurality of sensor parts arranged in matrix. A first electrode being connected with first wiring and a second electrode being connected with second wiring are disposed oppositely through a cavity part in the sensor part. The second electrode bends to the first electrode side in response to a pressure from a specimen and touches the first electrode upon application of a pressure of a specified level or above. When the specimen is pressed against a pressure detecting region, both electrodes touch each other at a sensor part corresponding to a protrusion of the specimen and are separated at a sensor part corresponding to a recess. When a scanning signal is fed from a scanning circuit to one wiring and presence of a signal flowing through the second wiring is detected by a sensing circuit, a pressure being applied to each sensor part can be detected. Furthermore, the shape is detected by feeding the scanning signal from the scanning circuit to each first wiring sequentially and scanning the pressure detecting region generally.

### TECHNICAL FIELD

The present invention relates to a pressure sensor and, more particularly, to a sensor for detecting a fine pattern.

### BACKGROUND ART

A finger print sensor has been conventionally employed as an individual identification device, and a requirement for the finger print sensor is detection of a finger print with simplicity and good precision. Various types of finger print sensors of this kind have been studied and developed, which include a type to detect a finger print optically, a type to detect a finger print electrically, and the like. JP-A 09-126918 (1997) and JP-A 10-300610 (1998) describe, for example, that microsensor sections having electrodes are arranged in a matrix, wherein a pressure from a finger is converted into an electric signal to thereby detect a finger print. The microsensor sections each are constructed such that two electrodes are disposed opposite each other with a cavity present therebetween.

FIG. 16 is a sectional view of a microsensor section in fabrication process. An etching barrier layer 102 is stacked on a silicon substrate 101 and a first metal layer 103 made of Au or Ti is formed thereon in a predetermined pattern. The first metal layer 103 is used as a first electrode of a variable capacitor or a first terminal of a microcontactor. A separation film 104 made of polycrystalline silicon or Al is formed on and covers the first metal layer 103, and a second metal layer 105 made of Au or Ti is formed on the separation film 104. An insulating film 106 made of silicon nitride covers all over the surface of the substrate 101. An opening 107 reaching as far as the separation film 104 is formed on the surface of the microsensor section through the second metal film 105 and the insulating film 106 to expose the separation film 104 to the outside in the opening 107. Note that this state is shown in FIG. 16. Thereafter, wet etching is applied to the substrate 101, in which a solution etches the separation film 104 made of polycrystalline silicon or Al to remove the separation film 104 and to form a cavity. After the etching, the opening 107 is closed with silicon nitride or the like to hermetically seal the cavity. When a pressure from a finger is imposed on the microsensor, the insulating film 106 and the second metal layer 105 is curved to the first metal layer 103 side depending on the pressure, to which situation an electric signal is outputted in response to thereby detect a pattern of a finger print.

The electrodes of each of the microsensor sections are connected to respective control circuits through wires in order to detect a state of a pressure imposed on each of the microsensor sections. In this situation, plural wires connected to the first metal layer 103 are arranged in a row direction, plural wires connected to the second metal layer 105 are arranged in a column direction, and microsensor sections are arranged in a region surrounded by the both wires. Therefore, since wires are located around each of the microsensor sections and areas occupied by the wires do not participate in finger print detection, a resolution of a microsensor is reduced by a power corresponding to a useless space occupied the wire areas. This leads to reduction of accuracy in detection of a fine pattern to be obtained by a finger print sensor.

On the other hand, first wires are connected to the first metal layer 103, second wires are connected to the second metal layer 105, and a scanning signal is supplied to the first wires to detect outputs of the second wires upon supply of the signal to thereby detect states of the microsensor sections. By patterning the same metal layer, the first metal layer 103 and the first wires are formed integrally with continuity in a shape that the first metal layer 103 of the microsensor sections is projected from the first wire. Similarly, by patterning the same metal layer, the second metal layer 105 and the second wires are formed integrally with continuity in a shape that the second metal layer 105 of the microsensor sections is projected from the second wire.

In FIG. 17, there is shown one example of detection states of the microsensor sections. Alphanumerical symbols S1 to S5 of FIG. 17 indicate the first wires and alphanumerical symbols L1 to L5 indicate the second wires, and the microsensor sections are disposed at intersections of the first wires and the second wires. Microsensor sections with oblique hatching indicate that they are under a pressure, in which the metal layers 103 and 105 are thereby in contact with each other. In such a situation, when a scanning signal is supplied to the first wire S3, the signal flows into the second wires L2 and L3 through the microsensor sections C2 and C3, and the scanning signal can be detected on the two second wires.

In a construction in which the electrodes of microsensor sections are made of the same material as the corresponding wires connected thereto integrally with continuity, a scanning signal flowing in a second wire has sometimes been flowed into another first wire through another microsensor section having not been scanned. That is, in FIG. 17, a signal flowing in the second wire L2 sometimes flows into the first wires S1 and S2 through the microsensor sections A2 and B2. Moreover, a signal flowing in the second wire L3 sometimes flows into the first wires S4 and S5 through the microsensor sections D3 and E3. Therefore, a signal flows into the second wires L1 and L4 through the microsensor sections A1 and E4 with the result that erroneous detection occurs that pressures are imposed on the microsensor sections C1 to C4, leading to reduction in precision.

### DISCLOSURE OF THE INVENTION

The present invention has been made in light of the above problems, and it is an object of the present invention to provide a high precision pressure sensor capable of increasing a proportion of an area occupied by sensor sections to improve resolution thereof and, also, decreasing chances of erroneous detection thereof.

In order to achieve the above object, the present invention is directed to a pressure sensor including: plural first wires and plural second wires intersecting with each other in arrangement; and sensor sections provided in the vicinities of the respective corresponding intersections, wherein each of the sensor sections includes: a first electrode electrically connected to the first wire; a second electrode disposed opposite to the first electrode; and a cavity formed between the first electrode and the second electrode, and the second wires work additionally as the second electrodes in the sensor sections.

The present invention is also directed to a pressure sensor including: plural first wires and plural second wires intersecting with each other in arrangement; and sensor sections provided in the vicinities of the respective corresponding intersections, wherein each of the sensor sections includes: a first electrode electrically connected to the first wire; a second electrode disposed opposite to the first electrode; and a cavity formed between the first electrode and the second electrode, and the first wires have larger width portions in respective spaces between adjacent sensor sections.

The present invention is also directed to a pressure sensor including: plural first wires and plural second wires intersecting with each other in arrangement; and sensor sections provided in the vicinities of the respective corresponding intersections, wherein each of the sensor sections includes: a first electrode electrically connected to the first wire; a second electrode disposed opposite to the first electrode; and a cavity formed between the first electrode and the second electrode, the second wires work additionally as the second electrodes, and the first wires have larger width portions in respective spaces between adjacent sensor sections.

The present invention is also directed to the pressure sensor with the above construction, wherein the first wires are connected to the first electrodes at the larger width portions.

The present invention is also directed to the pressure sensor with the above construction, wherein all of the first wires and all of the second wires extend outwardly from the outermost peripheral boundary portion where sensor sections along the outermost periphery are disposed.

The present invention is also directed to the pressure sensor with the above construction, wherein all of the first wires and all of the second wires extend outwardly from the outermost peripheral boundary portion by a length of 100 μm or more.

The present invention is also directed to the pressure sensor with the above construction, wherein dummy sensor sections are disposed in the outermost peripheral portion of a region including the sensor sections.

The present invention is also directed to the pressure sensor with the above construction, wherein the first wires are connected to the first electrodes through contact layers higher in resistance than the first wires.

The present invention is also directed to the pressure sensor with the above construction, wherein the contact layers are formed with a silicon layer mixed with a conductive impurity.

The present invention is also directed to the pressure sensor with the above construction, wherein the contact layers are formed with polycrystalline silicon.

The present invention is also directed to the pressure sensor with the above construction, wherein the first wires are connected to the first electrodes through switching elements.

The present invention is also directed to the pressure sensor with the above construction, wherein the switching elements are thin film transistors.

The present invention is also directed to the pressure sensor with the above construction, wherein a scanning signal is sequentially supplied onto the plural first wires.

### BRIEF DESCRIPTION OF THE DRAWINGS

FIG. 1 is an overall view schematically showing a pressure sensor according to a first embodiment of the present invention.

FIG. 2 is a plan view of sensor sections and vent hole sections of the pressure sensor.

FIG. 3 is a schematic sectional view of the sensor section.

FIG. 4 is a schematic sectional view of the vent hole section.

FIG. 5 is a schematic sectional view including the sensor section and the vent hole section.

FIGS. 6(a) to 6(h) are sectional views for describing steps of a fabrication process for the sensor section.

FIGS. 7(a) to 7(f) are plan views for describing steps of the fabrication process for the sensor section.

FIGS. 8(a) to 8(h) are sectional views for describing steps of a fabrication process for the vent hole section.

FIGS. 9(a) to 9(d) are plan views for describing steps of a fabrication process for the vent hole section.

FIG. 10 is a schematic view showing a pressure detection region according to a second embodiment of the present invention.

FIG. 11 is a schematic view showing a pressure detection region according to a third embodiment of the present invention.

FIG. 12 is a plan view of sensor sections and vent hole sections of a pressure sensor according to a fourth embodiment of the present invention.

FIG. 13 is a schematic sectional view of the sensor section.

FIG. 14 is a schematic view of a region in the vicinity of the outermost periphery of a pressure sensor according to a fifth embodiment of the present invention.

FIG. 15 is a schematic view showing a part of a pressure sensor according to a sixth embodiment of the present invention.

FIG. 16 is a sectional view showing a state of a conventional pressure sensor in a step of a fabrication process therefor.

FIG. 17 is an overall view showing a conventional pressure detection region.

### BEST MODE FOR CARRYING OUT THE INVENTION

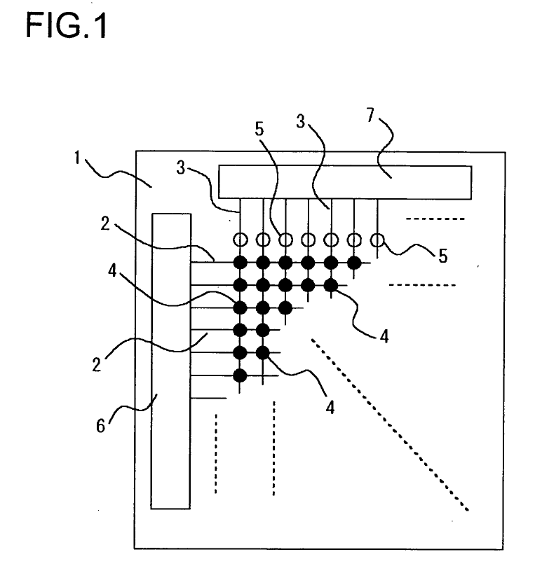

Hereinafter, description will be given of a first embodiment of the present invention with reference to the accompanying drawings. FIG. 1 is an overall view schematically showing pressure sensors of the present invention. A numerical symbol 1 indicates a transparent glass substrate, and intersections between plural first wires 2 extending in the row direction and plural second wires 3 extending in the column direction are arranged in a matrix on the glass substrate 1. In this embodiment, while the glass substrate 1 is used as a substrate, a plastic film or the like may also replace it without imposing specific limitation on the glass substrate. A numerical symbol 4 indicates sensor sections each disposed in the vicinity of intersections of the first wires 2 and the second wires 3, and a numerical symbols 5 indicates vent hole sections provided on the respective second wires 3. A region in which the plural sensor sections 4 are arranged in a matrix corresponds to a pressure detection region, which detects a fine pattern, and the vent hole section 5 is provided outside the pressure detection region. Note that there is provided a region for detecting a pattern in a pressure sensor device in which sensor sections 4 are assembled, and the term “pressure detection region” herein means not a region for detecting a pattern in the pressure sensor device, but a region in which the sensor sections 4 exist. The vent hole sections 5 are located on respective extensions in the column direction along which the sensor sections 4 are disposed, wherein two vent hole sections are disposed at both ends of each sensor section group disposed in a line along the column direction. Note that one vent hole section 5 may be disposed adjacent to one end of each sensor group in a line. A numerical symbol 6 indicates a scanning circuit for supplying a scanning signal to the first wires 2, and a numerical symbol 7 indicates a sensing circuit for detecting a signal flowing in the second wires 3.

In the sensor section 4, a detailed construction of which will be described later, a first electrode connected to the first wire 2 and a second electrode connected to the second wire 3 are disposed opposite to each other with a cavity interposed therebetween. The second electrode is curved to the first electrode side so as to match a pressure from a specimen to be eventually brought into contact with the first electrode when a pressure of a predetermined value or more is applied. When the specimen is pushed to the pressure detection region, both electrodes are brought into contact with each other in a sensor section 4 corresponding to a protrusion of the specimen, while both electrodes are kept separated from each other in a sensor section 4 corresponding to a depression of the specimen. If in this situation, a scanning signal is supplied to one of the first wires 2 from the scanning circuit 6, the signal flows into a second wire 3 through both electrodes in a sensor section 4 in which both electrodes are brought into contact, while no signal flows into a second wire 3 in a sensor section 4 in which both electrodes are not brought into contact. Then, if the presence/absence of the signal flowing through a second wire 3 is detected in the sensing circuit 7, pressures imposed on each of the sensor sections 4 can be detected. A scanning signal is supplied sequentially to the first wires 2 from the scanning circuit 6 to thereby scan all of the pressure detection region with the signal once and to detect a pattern.

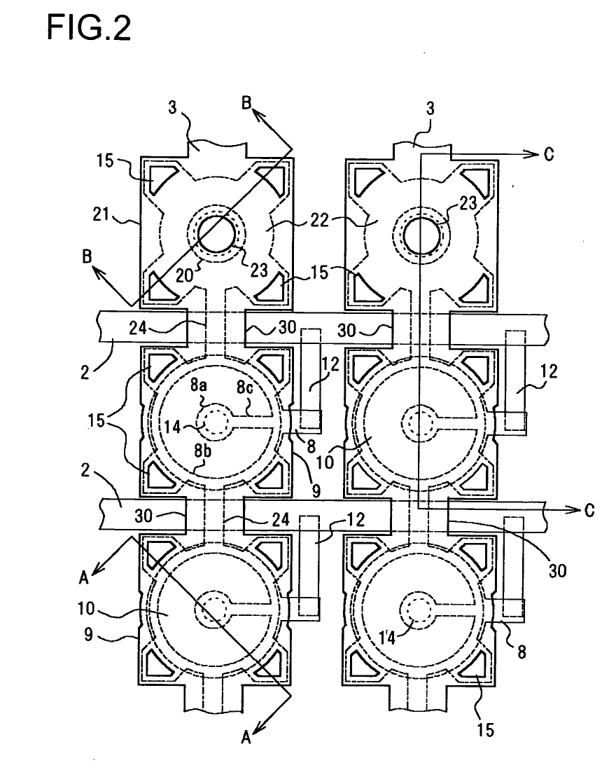

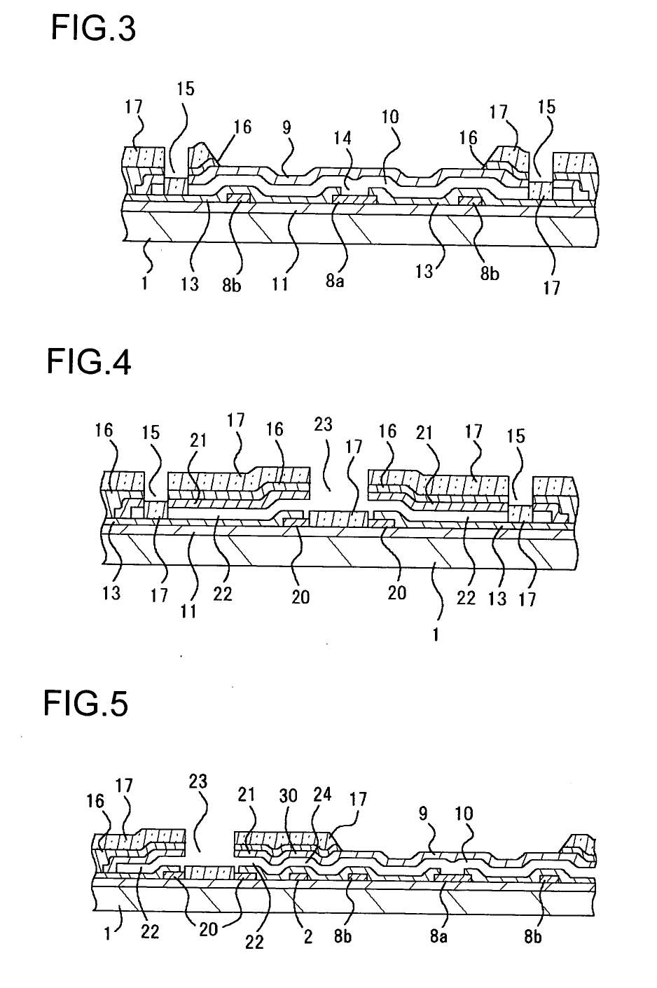

FIG. 2 is a plan view of the sensor sections 4 and the vent hole section 5 of the pressure sensor, FIG. 3 is a sectional view of the sensor section 4 taken along line A-A of FIG. 2, FIG. 4 is a sectional view of the vent hole section 5 taken along line B-B of FIG. 2 and FIG. 5 is a sectional view taken along line C-C of FIG. 2.

First of all, description will be given of a structure of a sensor section 4. A lower-layer insulating film 11 made of SiNx is stacked all over the surface of the glass substrate 1. Plural first wires 2 are disposed in parallel to each other on the lower-layer insulating film 11, and a first electrode 8 is formed in the sensor section 4. The first wire 2 and the first electrode 8 both are formed by patterning a metal layer stacked on the lower-layer insulating film 11. Used as a metal layer is, for example, a layer structure made of Al and Mo. The first electrode 8 includes: a circular portion 8a located in the central portion and corresponding to a central electrode portion of the sensor section 4; an annular portion 8b disposed in the periphery of the sensor section 4; and a connection portion 8c connecting the circular portion 8a and the annular portion 8b thereby.

A numerical symbol 12 indicates a long, narrow contact layer for electrically connecting the first wire 2 and the first electrode 8, which is made of an amorphous silicon layer, a polycrystalline layer or a metal layer. The contact layer 12 is made of a material higher in resistivity than metals of which the first wire 2 and the first electrode 8 are made. If herein, a resistance value of the contact layer 12 is R, a voltage of a scanning signal supplied to the first wire 2 is E, and a current flowing through the second wire 3 is I by definition, a relation of E=IR is established. Therefore, a signal flowing into a second wire 3 through one sensor section 4 is of a current value of I. A signal flowing through the second wire 3, however, further flows in a sensor section 4, in a first wire 2 having not been scanned, in a sensor section 4 on another column and in a second wire 3 on another column, the scanning signal eventually passes through three contact layers 12 counted from the first wire 2 originally applied with the scanning signal. If a current flowing in the second wire 3 on another column is I′ by definition, a relation of E=3RI′ is established to thereby give a relation of I′=I/3. Therefore, by measuring current values in the second wires 3, it is determined whether or not a current has passed through other sensor sections 4, thereby enabling a precision of a sensor itself to be improved.

The contact layer 12 is preferably a layer that can be uniformly formed in thickness and on which a pattern can be formed using optical means, and used herein is preferably a polycrystalline silicon layer or an amorphous silicon layer mixed with a conductive impurity.

In a case where the contact layer 12 are made of n⁺a-Si, an Si layer is stacked on the lower-layer insulating film 11 to a thickness in the range of 50 to 3000 angstroms and P or B is ion doped into the Si layer at a doze in the range of 1.0×10¹¹ to 1.0×10¹⁵/cm². Thereafter, the Si layer is patterned to form the contact layers 12, and the first wires 2 and the first electrodes 8 are formed so that the first wire 2 and the first electrodes 8 partly overlap the contact layers 12. In this case, no necessity arises for a step such as annealing treatment as compared with a case where polycrystalline Si is used, which makes fabrication easy. Moreover, since resistivity is higher than the polycrystalline Si, the contact layer 12 can be shorter by a length corresponding to increase in resistivity to improve resolution by integrating sensor sections at a higher packing density.

In a case where the contact layers 12 are made of polycrystalline Si, a Si layer is stacked on the lower-layer insulating film 11 and is subjected to annealing treatment and patterning treatment to thereby form the polycrystalline contact layers 12. A thickness of the contact layer 12 thus formed is suitably in the range of 200 to 1000 angstroms. Ion doping into the contact layer 12, and formation of the first wires 2 and the first electrodes 8 are performed in similar ways to those in the case of n⁺a-Si.

Resistance of the contact layer 12 is determined based on the minimum current value detectable in the sensing circuit 7. In a case where a highly resistant contact layer 12 is employed, wiring resistance is necessary to be reduced. Since a resistance value is proportional to a distance, the larger a distance from the scanning circuit 6, the higher a resistance value to as far as the scanning circuit 6. Hence, in a case where wire resistance from the scanning circuit 6 to a sensor section 4 located at a position farther from the scanning circuit 6 is on the same order as that of the contact layer 12, none of results of the detection in the sensing circuit 7 give proper information on which of the results is a proper value. Therefore, the first wire 2 preferably contains Al or the like low in resistivity.

A numerical symbol 13 indicates a first insulating film made of SiNx, SiO₂ or the like and covers the lower-layer insulating film 11 and the first wires 2. The first insulating film 13 also exists in the sensor section 4 and a sensor hole 14 in the shape of a circle is formed in the vicinity of the center of the sensor section 4 to expose the central portion of a circular portion 8a of the first electrode 8. A size and thickness of the sensor hole 14 (a thickness of the first insulating film 13 at the periphery of the sensor hole 14) affect a sensitivity of the sensor.

Since the first insulating film 13 covers the periphery of the circular portion 8a of the first electrode 8, the second electrode 9 is not brought into close contact with the first electrode 8 at a large area and, after the second electrode 9 is brought into contact with the first electrode 8, the second electrode 9 starts being separated from the first electrode 9 from a point in the vicinity of the first insulating film 13. The thicker the first insulating film 13, the second electrode 9 restores the original state with more of ease even if elasticity of the second electrode 9 is weaker, with a lower possibility that the second electrode 9 is brought into contact with the first electrode 8.

In a case where the sensor hole 14 is larger, an exposed portion of the first electrode 8 increases, which results in a higher possibility of the first electrode 8 being brought into contact with the second electrode 9. Therefore, detection of a lower pressure imposed onto the sensor section 4 can be realized, whereas overdetection is easier to occur by increase in sensitivity to detect a low pressure. Contrary thereto, in a case where the sensor hole 14 is smaller, an exposed portion of the first electrode 8 decreases, which results in a lower possibility of the first electrode 8 being brought into contact with the second electrode 9; therefore, the sensor is more insensitive to a pressure by decrease in possibility of the contact. Note that while in this embodiment, the sensor hole 14 is circular, it is not specifically limited to this shape and may also be in the shape of a tetragon or the like.

The first electrode 8 exposed from the first insulating film 13 is disposed opposite to the second electrode 9 with the cavity 10 interposed therebetween. The cavity 10, of which a forming method will be described later, extends to as far as the annular portion 8b of the first electrode 8 in the horizontal direction of the sensor section 4. Release holes 15 are provided at four corners of the sensor section 4 and the cavity 10 extends to the release holes 15.

The second electrode 9 is formed with a metal layer and, for example, Mo is used as a metal of the layer. In the sensor section 4, the second electrode 9 is patterned into a square of 50 μm×50 μm in size and the release holes 15 are opened at the four corners. In the sensor sections 4 disposed in the column direction, a connection portion 30 is formed that electrically connects between the second electrodes 9 of sensor sections 4 adjacent to each other, and the second electrodes 9 and connection portions 30 play a second role as the second wire 3. The connection portion 30 is narrower in width than the second electrode 9, and is overlapped with the first wire 2 through the first insulating film 13 in an orthogonal direction. Description will be given of a fabrication process for the second electrodes 9 and the connection portions 30 later, which are formed by patterning the same metal layer.

A numerical symbol 16 indicates a second insulating film and a numerical symbol 17 indicates a protective film, which films are stacked on the first insulating film 13 and the second wire 2. In this embodiment, both films are made of SiNx. Note that a material of the films 16 and 17 are not specifically limited to SiNx, and may be SiO₂ or an organic insulating material such as polyimide, polyacrylate or the like. Though details will be given later, the second insulating film 16 and the protective film 17 are formed individually in respective separate steps. The release holes 15 are formed in the second insulating film 16 and the protective film 17 is formed on the second insulating film 16 after formation of the release holes 15; therefore the release holes 15 are closed with the protective film 17. The protective film 17 closing the release holes 15 and the protective film 17 stacked on the second insulating film 16 are simultaneously formed, but both are not continuous and separated. The protective film 17 closing the release hole 15 corresponds to a closed portion.

In the sensor section 4, the second insulating film 16 and the protective film 17 on the second electrode 9 are removed so as to form an empty circle surrounded with both films to thereby expose the second electrode 9. Since the second electrode 9 is curved at the boundary between the exposed portion and the surrounding second insulating film 16 as a supporting point, a flexibility of the second electrode 9 changes according to the magnitude of an area where the second insulating film 16 is removed. If the second insulating film 16 is removed in a larger area, the second electrode 9 is easier to be curved and when a protrusion of a specimen is brought into contact with the second electrode 9, the second electrode 9 is curved to contact the first electrode 8; therefore, the sensor section 4 is more sensitive to a pressure. Contrary thereto, if the second insulating film 16 and the protective film 17 are left on the second electrode 9, the second electrode 9 is harder to be curved correspondingly; therefore, the sensor section 4 is less sensitive to a pressure. Easiness in curving of the second electrode 9 affects a sensitivity of the sensor section 4, and the more sensitive the sensor section 4 is to a pressure, a pattern of the specimen is detected more indefinite due to overdetection of the pressure, while on the other hand, the less sensitive the sensor section 4 is to a pressure, there arises a portion where a fine pattern of the specimen cannot be detected and a pattern of the specimen is detected with less of sharpness. Therefore, excessive sensitivity or excessive insensitivity contributes to increase in possibility of erroneous detection, which necessitates a design in which easiness in curving of the second electrode 9 is properly set. If the boundary between a removed area of the second insulating film 16 and the rest of the film is set so as to be located inside the annular portion 8b on the outermost side of the first electrode 8, a flexibility and restoring force of the second electrode 9 fall within proper ranges.

Furthermore, the second insulating film 16 and the protective film 17 in the form of a thin film present on the second electrode 9 play roles of reinforcement and protection, which reduces breakage of the second electrode 9 to some extent corresponding to the reinforcement and protection. While in this embodiment, the second insulating film 16 and the protective film 17 are removed partly in an area to the full depth thereof, the second insulating film 16 and the protective film 17 may be removed partly in an area part way deeply in the thickness so that a central portion is thinner than the rest. In the latter case, the thinner portion is preferably in the shape of a circle with the center of the sensor section 4 as the center thereof. Note that while in this embodiment, the second insulating film 16 is removed in a circle, the film may be removed in a tetragon.

Then, description will be given of the vent hole section 5. A numerical symbol 20 indicates a dummy electrode positioned in the vicinity of the center of the vent hole section 5 and formed on the lower-layer insulating film 11. The dummy electrode 20 is a metal layer in the shape of a doughnut having an opening in the center thereof and formed in the same step as the first wire 2 and the first electrode 8. Therefore, for example, a metal layer of a layer structure made of Mo and Al is stacked all over the surface of the lower-layer insulating film 11, and the metal layer is patterned to form the dummy electrode 20, the first wire 2 and the first electrode 8 simultaneously. The dummy electrode 20 is not electrically connected to the first wire 2 and formed isolatedly. The first insulating film 13 is stacked so as to cover the lower-layer insulating film 11 and the dummy electrode 20, and is removed in the vicinity of the center of the vent hole section 5 to expose parts of the lower-layer insulating film 11 and the dummy electrode 20.

A numerical symbol 21 indicates an auxiliary electrode located in the vent hole section 5, and the auxiliary electrode 21 is a metal layer made of Mo and the like similar to the second electrode 9 of the sensor section 4 and formed in the shape of a square having a size of 50 μm×50 μm, and the release holes 15 are formed in the metal layer at four corners thereof. The auxiliary electrode 21 of the vent hole section 5 is analogous to the second electrode 9 of the sensor section 4 in the shape, while having no function to detect a pattern and exists as part of the second wire 3. A second cavity 22 is provided between the auxiliary electrode 21 and the first insulating film 13 and spatially communicates with the cavity 10 of the sensor section 4 to make both cavities 10 and 22 to be ventilatable therebetween. The second insulating film 16 is stacked on the auxiliary electrode 21 and the release holes 15 are provided therein in a similar manner to that in the auxiliary electrode 21.

A vent hole 23 passing through the auxiliary electrode 21 and the second insulating film 16 is formed in the center of the vent hole section 5. The dummy electrode 20 and the first insulating film 13 are not present in a place corresponding to the vent hole 23. When the protective film 17 is stacked on the second insulating film 16, the release holes 15 are closed with part of the protective film 17 to thereby disconnect a communicating state with the second cavity 22, while since in the vent hole 23, the protective film 17 is stacked on the lower-layer insulating film 11, the communicating state with the second cavity 22 are maintained. In the vent hole section 5, the second insulating film 16 and the protective film 17 on the auxiliary electrode 21 are not removed and remain as they are. Therefore, curving in the auxiliary electrode 21 is restricted by the second insulating film 16 and the protective film 17, the peripheral area of the vent hole 23 is reinforced and, thereby, the vent hole 23 continues to communicate with the second cavity 22 even during fabrication or operation thereof.

A numerical symbol 24 indicates a communication path hollow in the interior to ventilate air therein, the communication path is located between the vent hole section 5 and the sensor section 4 and between adjacent sensor sections 4, and communicates between the cavities 10 in the sensor sections 4 and between the cavity 10 of the sensor section 4 and the second cavity 22 of the vent hole section 5. The communication path 24 is constructed with the first insulating film 13 at the bottom and with the connection portion 30 made of a metal layer of the second wire 3, at the side surfaces and the top surface. The cavities 10 of the sensor sections 4 and the second cavities 22 of the vent hole sections 5 spatially communicate with each other by the communication paths 24 and the outside air can be ventilated through the vent holes 23. Since a lateral width of the communication path 24 is narrower than that of the cavity 10, dust coming from the vent hole 23 can be prevented from intruding into the cavity 10 through the communication path 24.

With such a construction, even after the release holes 15 are closed with the protective film 17, the cavity 10 of the sensor section 4 can be kept at almost the same pressure as the outside air pressure. Therefore, no large load is imposed on the second electrode 9 of the sensor section 4 during a step of creating a vacuum, thereby enabling the second electrode 9 from being broken. Since the vent hole section 5 is provided separately from the sensor sections 4, dust is prevented from intruding into the cavity 10 of the sensor sections 4, thereby enabling a pressure sensor with fewer troubles to be obtained.

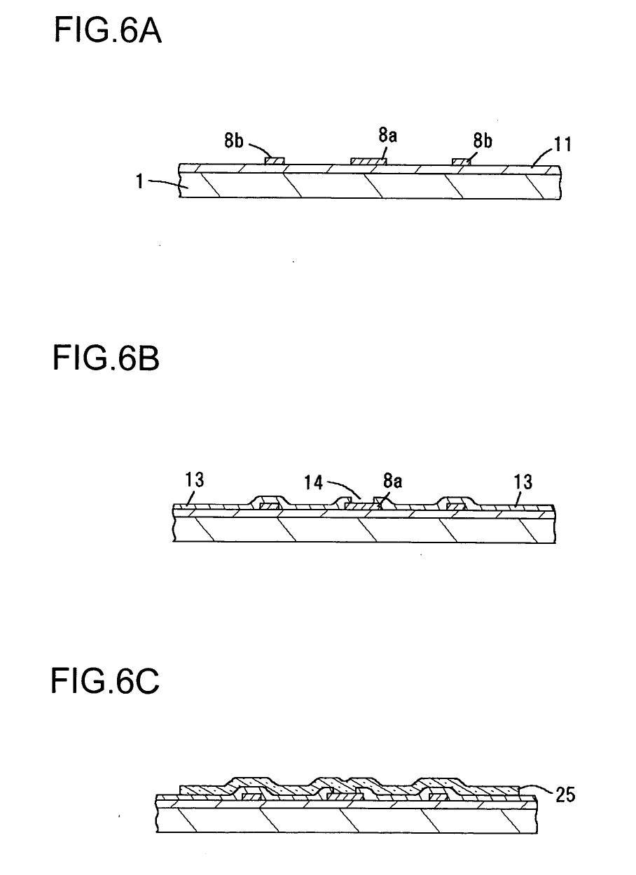

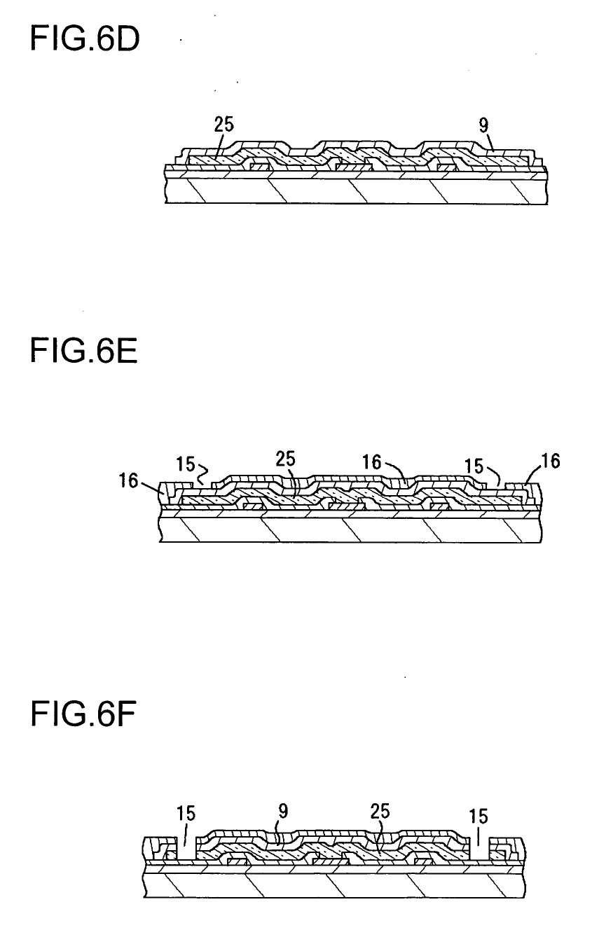

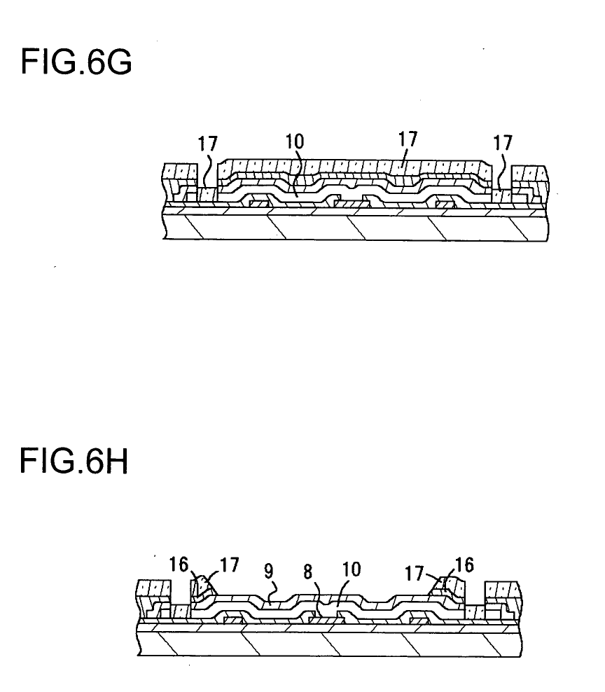

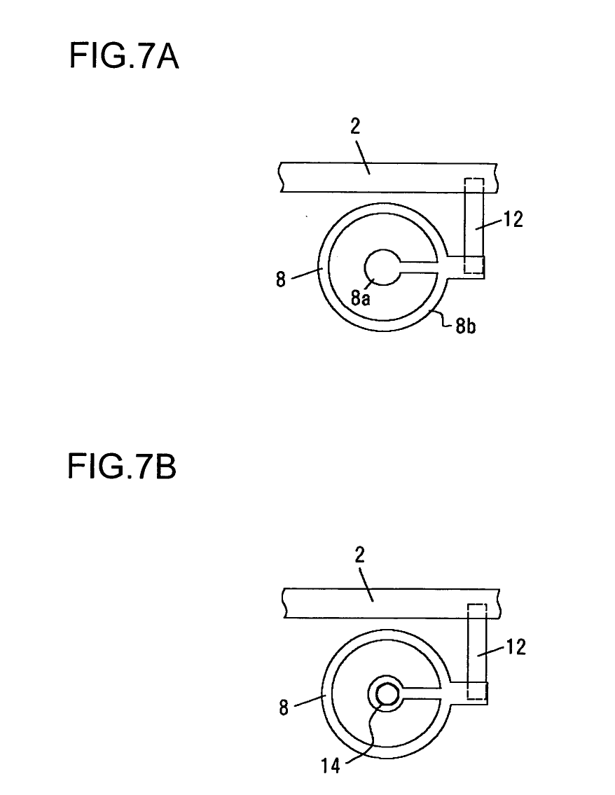

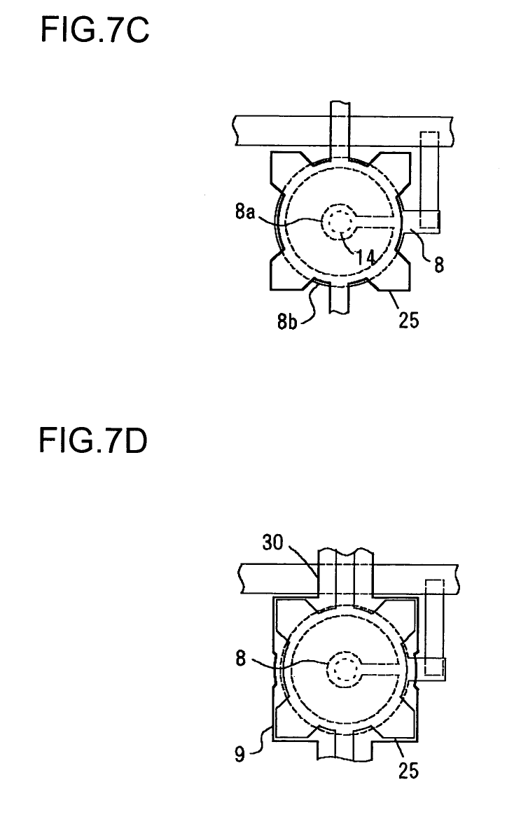

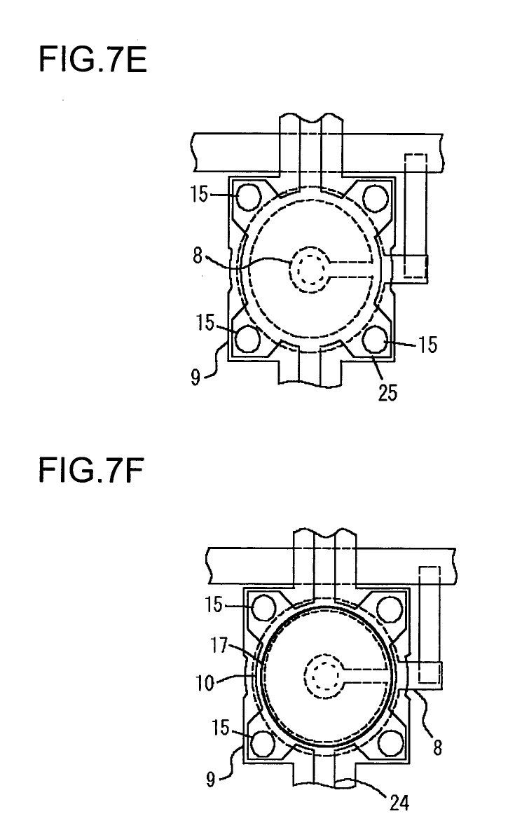

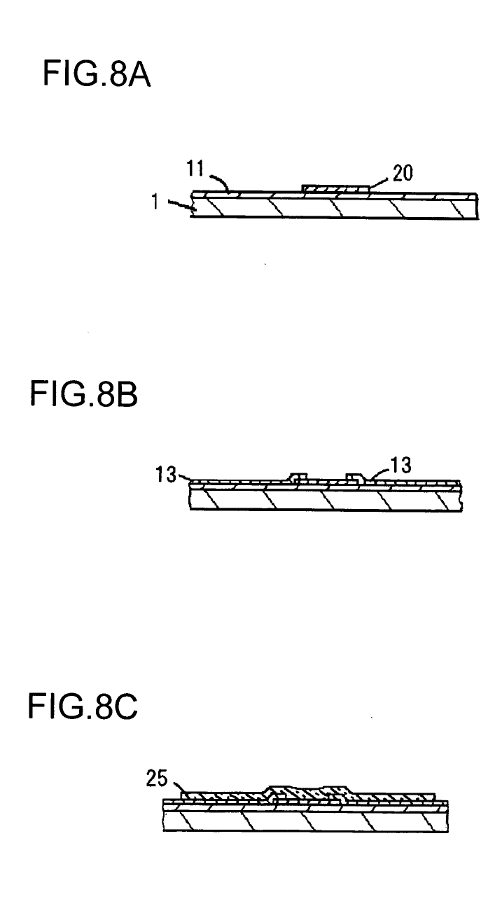

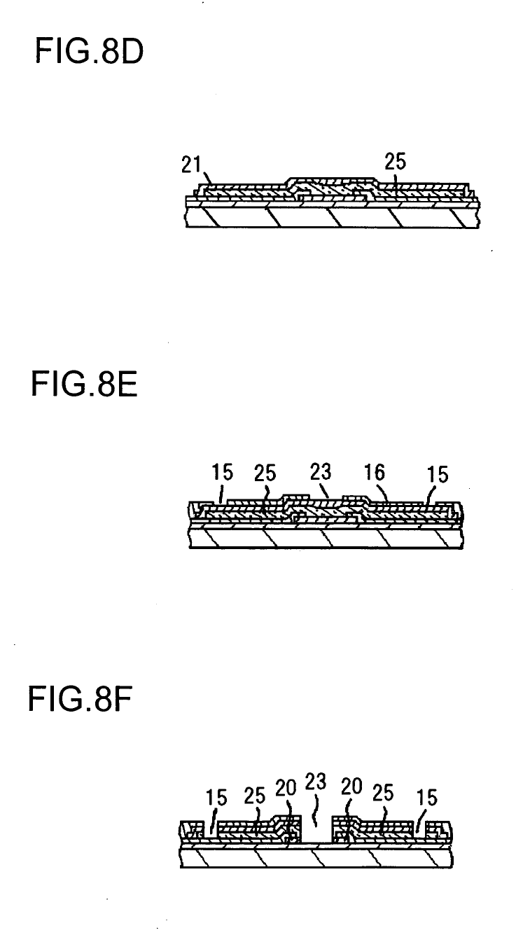

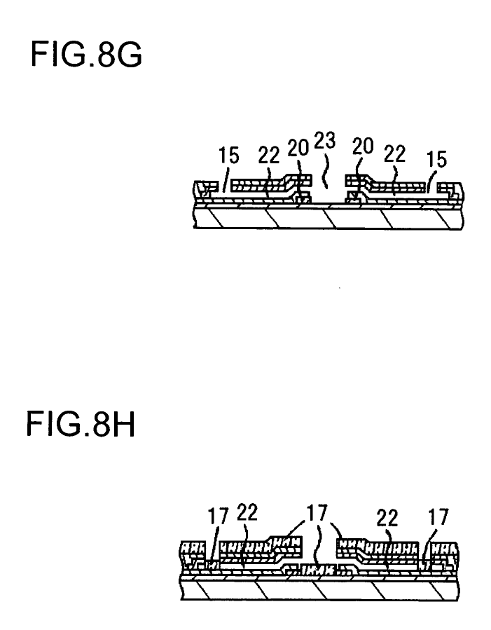

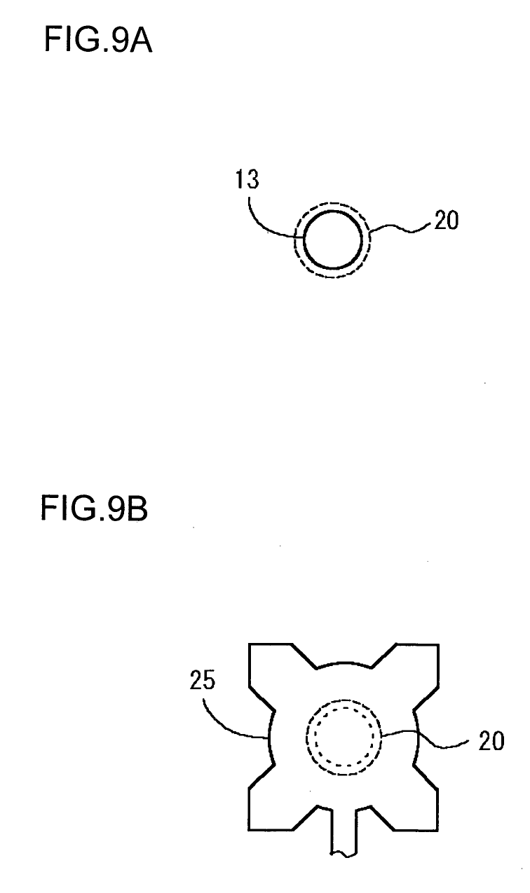

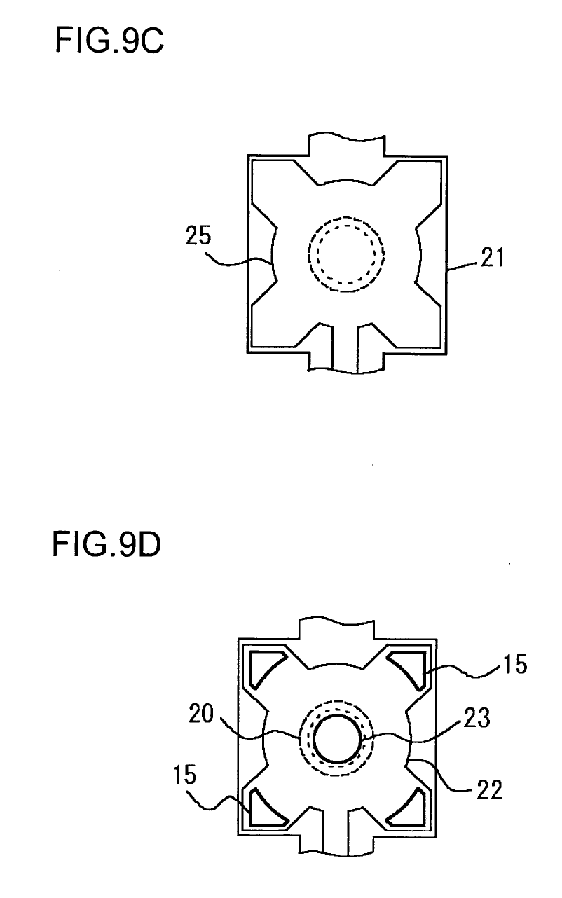

Then, description will be given of a fabrication process for the sensor section 4 based on the accompanying drawings. FIGS. 6(a) to 6(h) are sectional views (corresponding to the sectional view of FIG. 3) for describing steps of a fabrication process for the sensor section 4, FIGS. 7(a) to 7(f) are plan views for describing steps of the fabrication process for the sensor section 4, FIGS. 8(a) to 8(h) are sectional views (corresponding to the sectional view of FIG. 4) for describing steps of a fabrication process for the vent hole section 5, and FIGS. 9(a) to 9(d) are plan views for describing steps of a fabrication process for the vent hole section 5.

The lower-layer insulating film 11 made of SiNx is stacked on the glass substrate 1 and the Si layer is stacked on the lower-layer insulating layer 11. In the case where the contact layer 12 is made of n⁺a-Si, the Si layer is ion doped with P or B and, then, is patterned to leave behind only the Si layer in portions corresponding to the contact layers 12. In this case, a sheet resistance is set in the range of 2.7 to 35×10⁶ Ω/□. Note that in a case where the contact layer is formed with polycrystalline Si, an Si layer is formed and, thereafter, is applied with a dehydrogenation process, a sleight process, a laser annealing process and others so as to be polycrystallized and thereafter, the Si layer is left behind by means of a photolithographic method in a similar way to that in the case of n⁺a-Si. In the latter case, a sheet resistance is set to almost 0.035×10⁶ Ω/□. Thereafter, a metal layer of a layer structure made of Mo and Al is formed on the lower-layer insulating film II by means of a sputtering method or the like, and then, as shown in FIGS. 6(a), 7(a) and 8(a), the first wire 2, the first electrode 8 and the dummy electrode 20 are formed by means of a photolithographic method. In this case, the dummy electrode 20 is formed in the shape of a disk without an opening in the center thereof.

Then, SiNx is stacked on the lower-layer insulating film 11 and the first wire 2 to form the first insulating film 13. Then, in an etching step, the first insulating film 13 is removed in portions thereof corresponding to the circular section 8a and the dummy electrode 20. In the sensor section 4, as shown in FIGS. 6(b) and 7(b), the first insulating film 13 on the circular portion 8a is removed in a circle to form the sensor hole 14. In this way, the central portion of the circular portion 8a is exposed and the peripheral portion of the circular portion 8a is covered with the first insulating film 13. In the vent hole section 5, as shown in FIGS. 8(b) and 9(a), the first insulating film 13 on the dummy electrode 20 is removed in a circle. In this way, the central portion of the dummy electrode 20 is exposed and the peripheral portion of the dummy electrode 20 is covered with the first insulating film 13. The etched portion of the first insulating film 13 on the dummy electrode 20 is larger than the vent hole 23. A proportion of the first insulating film 13 present on the circular portion 8a affects a sensitivity of the pressure sensor, while a proportion of the first insulating film 13 present on the dummy electrode 20 affects a size of the vent hole 23.

Then, a metal layer made of Al is stacked on the first insulating film 13, the exposed first electrode 8 and the exposed dummy electrode 20. Thereafter, the metal layer is patterned by means of a photolithographic method or the like into predetermined arrangement of features to form the intermediate layer 25. While the intermediate layer 25 is finally removed, a space occupied by the intermediate layer 25 is formed as the cavity 10, the second cavity 22 and the communication path 24. Therefore, formed in the sensor section 4 is the intermediate layer 25 with a profile shown in FIGS. 6(c) and 7(c) and formed in the vent hole section 5 is the intermediate layer 25 with a profile shown in FIGS. 8(c) and 9(b). The intermediate layer 25 in the sensor section 4 includes: an almost circular portion covering from the circular portion 8a to as far as the annular portion 8b of the first electrode 8; and portions projected from the almost circular portion and extending to the four release holes 15. The intermediate layer 25 in the vent hole section 5 is in almost the same shape as the intermediate layer 25 in the sensor section 4. Since the dummy electrode 20 in the vent hole section 5 exists only in the vicinity of the center, no metal layer such as the annular portion 8b of the first electrode 8 is in the vent hole section 5, while the intermediate layer 25 includes: a circular portion covering a great part of the vent hole portion 5 including the dummy electrode 20 and portions projected from the circular portion and extending to as far as the release holes 15. The narrow, long intermediate layer 25 corresponding to the communication path 24 exists between adjacent sensor sections 4 and between a sensor section 4 and a vent hole section 5. Therefore, sensor sections 4 and a vent hole section 5 disposed in one column direction have the intermediate layer 25 existing continuously therein without disconnection. Note that shapes of the intermediate layer 25 in portions and thickness values thereof are designed so as to match the shapes and sizes of the cavities 10, the second cavity 22 and the communication paths 24, which are desired.

Then, a metal layer is stacked on the intermediate layer 25 and the first insulating film 13 by means of a sputtering method. The metal layer is of a layer structure made of Mo and Al. A resist is coated on the metal layer and is applied with exposure, development and etching treatment by means of a photolithographic method to form the second wire 3 including the second electrodes 9 and the connection portions 30. In this situation, the intermediate layer 25 is perfectly covered with the metal layer serving as the second wire 3. As shown in FIGS. 6(d) and 7(d), formed in the sensor section 4 is the second electrode 9 in the shape of almost a tetragon perfectly covering the intermediate layer 25. In this situation, no release hole 15 is formed in the second electrode 9. As shown in FIGS. 8(d) and 9(c), formed in the vent hole section 5 as well is the auxiliary electrode 21 in the shape of almost a tetragon perfectly covering the intermediate layer 25, and in this step, neither release holes 15 nor a vent hole 23 is formed in the auxiliary electrode 21. The intermediate layer 25 used for forming the communication paths 24 are covered with the connection portions 30, and a connection portion 30 electrically connects between the second electrodes 9 in the adjacent sensor sections 4.

Then, SiNx is stacked on the second electrode 9 and the first insulating film 13 to form the second insulating film 16. Then, as shown in FIGS. 6(e) and 7(e), removed in the sensor section 4 is SiNx in portions corresponding to the release holes 15 and, as shown in FIG. 8(e), removed in the vent hole section 5 is SiNx in portions corresponding to the release holes 15 and the vent hole 23. The portions in which the second insulating film 16 has been removed expose part of the second electrode 9 and part of the auxiliary electrode 21.

Then, both materials of Mo and Al are etched off. Removed by applying the etching treatment is the metal layer in portions exposed without coverage of the second insulating film 16. As etching methods, there can be used both of dry etching and wet etching. For example, if a mixture of phosphoric acid, nitric acid and acetic acid is used as an etching solution, Mo and Al are both etched off. With this etching treatment applied, as shown in FIG. 6(f), removed in the sensor section 4 are the second electrode 9 and the intermediate layer 25 in portions corresponding to the release holes 15. As shown in FIG. 8(f), removed in the vent hole section 5 are the auxiliary electrode 21, the intermediate layer 25 in portions corresponding to the release holes 15 and the auxiliary electrode 21, the intermediate layer 25 and the dummy electrode 20 in portions corresponding to the vent hole 23.

Then, etching treatment is applied to remove only the intermediate layer 25. In this step, a wet etching solution is adopted, and a mixture of hydrochloric acid, phosphoric acid and water is used as an etching solution. The etching solution reaches the intermediate layer 25 through the release hole 15 to etch off the intermediate layer 25 from the end thereof sequentially into the interior. In a case of use of an etching solution of a mixture of hydrochloric acid:phosphoric acid:water=1:5:1 in mixing ratio, a galvanic effect occurs between Al in the intermediate layer 25 and Mo of which the second wire 3 is made to thereby etch off Al in a short time. In a case where Al is aggressively etched off with the galvanic effect, an etching solution especially containing phosphoric acid in volume five or more times that of hydrochloric acid exerts the effect, whereas in a case of use of an etching solution of a mixture of hydrochloric acid:phosphoric acid=1:5 in mixing ratio, a lot of gas bubbles are generated simultaneously during etching. To cope with such generation of gas bubbles, studies have been conducted with experiments with the results that in a case of use of an etching solution of a mixture of hydrochloric acid:phosphoric acid:water=1:10:1, Al can be aggressively etched off in a short time with fewer gas bubbles generated. With this etching treatment adopted, the intermediate layer 25 can be surely removed to form each of the cavities 10 and 22 and the communication path 24 (FIGS. 8(g) and 9(d)).

Thereafter, SiNx is stacked on the second insulating film 16 to form the protective film 17. SiNx is formed, for example, by CVD and a film with almost a uniform thickness is stacked all over the surface of the glass substrate 1. In this step, since no second insulating film 16 exists in the release holes 15 and the vent hole 23, the protective film 17 is stacked on the first insulating film 13 in the release holes 15, while being stacked on the lower-layer insulating film 11 in the vent hole 23. The protective film 17 is formed to close the release holes 15 in the sensor section 4, but at the same time, a thickness thereof is set not to close the vent hole 23 in the vent hole section 5 thereby. Since the cavity 10 is formed using the intermediate layer 25, a thickness of the intermediate layer 25 is that of the cavity 10 and the cavity 10 is at an almost uniform thickness therein. A thickness of the cavity 10 corresponds to a distance of the bottom surface of the lower space of the release hole 15 to the release hole 15. Therefore, if a thickness of the cavity 10 is d1 and a thickness of the protective film 17 (a closed portion) closing the release hole 15 is d by definition, the release hole 15 can be closed with certainty if a relation of d1≦d is established. In contrast thereto, since the first insulating film 13 and the dummy electrode 20 are present in the peripheral area of the vent hole 23, but are removed in the vent hole 23, the bottom surface of the vent hole 23 is lower than the bottom surface of the release hole 15. Therefore, if a distance from the bottom surface of the lower space of the vent hole 23 to the vent hole 23 is d2, a thickness of the first insulating film 13 is d3, a thickness of the dummy electrode 20 is d4 by definition, a relation of d2=d1+d3+d4 is established, and the vent hole 23 is not closed even in a state where the protective film 17 is stacked if a relation d<d2 is established. By stacking the protective film 17 satisfying this condition, the release holes 15 are, as shown in FIG. 6(g), closed in the sensor section 4 and dust can be prevented from intruding into the cavity 10 through the release hole 15. In the vent hole section 5, since the vent holes 23, as shown in FIG. 8(h), communicates with the second cavity 22, a pressure in the cavity 10 of the sensor section 4 can be almost the same as in the outside air.

Thereafter, as shown in FIGS. 6(h) and 7(f), removed are the second insulating film 16 and the protective film 17 on the second electrode 9 in the sensor section 4. The second insulating film 16 and the protective film 17 are removed in a region covering the circular portion 8a to the annular portion 8b of the first electrode 8 and, thereby, the second electrode 9 in the region is easier to be curved. With such a construction adopted, the sensor section 4 sensitive to a pressure can be formed.

Even if in such a way, the cavity 10 is formed in the sensor section 4 and the release holes 15 used for forming the cavity 10 are closed, the cavity 10 is maintained in a state where it can communicate with the outside air. Therefore, even if the sensor section 4 is placed in a space in which a vacuum has been created in a later step of a fabrication process, it is prevented from occurring a large difference between air pressures in and outside the cavity 10, with the result of no great load on the second electrode 9. Therefore, the sensor section 4 is prevented from being broken to increase a product yield.

Since in this embodiment, the second electrodes 9 in the sensor sections 4 work additionally as a second wire 3, no necessity arises for providing a special space for disposing the second wire 3, thereby enabling the sensor sections 4 to be disposed in a higher packing density by increase in complexity corresponding to a saved apace. Therefore, a proportion of the sensor sections 4 in the pressure detection region is increased with improved resolution. Moreover, since the second electrodes 9 and the connection portions 30 are simultaneously formed by patterning the same metal layer, the connection portions can be formed with a simple process.

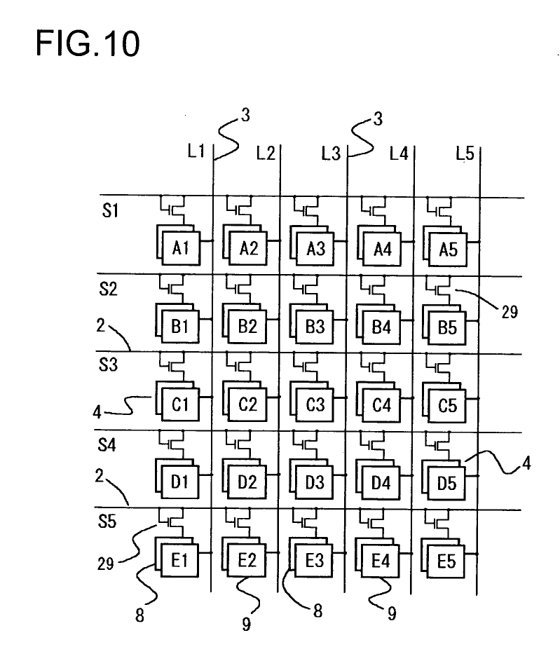

While in this embodiment, a first wire 2 is connected to first electrodes 8 with contact layers 12 higher in resistance than the first wire 2, switching elements may also be provided instead of the contact layers 12 with a higher resistance value. FIG. 10 is a schematic view showing a pressure detection region in which thin film transistors 29 (hereinafter referred to as TFT) are provided as switching elements. A first wire 2 is connected to first electrodes 8 with the TFTs 29, the gate electrode and source electrode of each TFT 29 are connected to the first wire 2, and the drain electrode of each TFT 29 is connected to a corresponding first electrode 8. The TFTs 29 are made of a-Si or p-Si and a size of a channel portion thereof is such that a channel length L is in the range of 3 to 10 μm and a channel width W is in the range of 5 to 30 μm. Note that shapes of the sensor sections 4 and the vent hole sections 5 are the same as in the above embodiment.

In FIG. 10, the TFTs 29 connected to a first wire 2 onto which a scanning signal is supplied are turned on to thereby supply the scanning signal to the first electrode 8. Since the TFTs 29 connected to a first wire 2 onto which no scanning signal is supplied are turned off, the signal flowing in the corresponding second wire 3 is, even if being transmitted to a second electrode 9 and first electrode 8 in a sensor section 4 on which no scanning signal is supplied, prevented from transmitted to another first wire 2 from the first electrode 8.

Note that while description is given of the case where a first wire 2 is connected to first electrodes 8 with the TFTs 29, a second wire 3 may be connected to second electrodes 9 may be connected with the TFTs 29 instead. In this case, the second wires 3 are not formed being connected to second electrodes 9 and the second wires 3 are formed separately from the second electrodes 9. The gate electrode and source electrode of each TFT is connected to the corresponding second electrode 9 and the drain electrode thereof is connected to the second wire. With such a construction, the TFT is turned on when a scanning signal is inputted to a second electrode 9 through a first electrode 8 to thereby cause the signal to flow in the corresponding second wire 3.

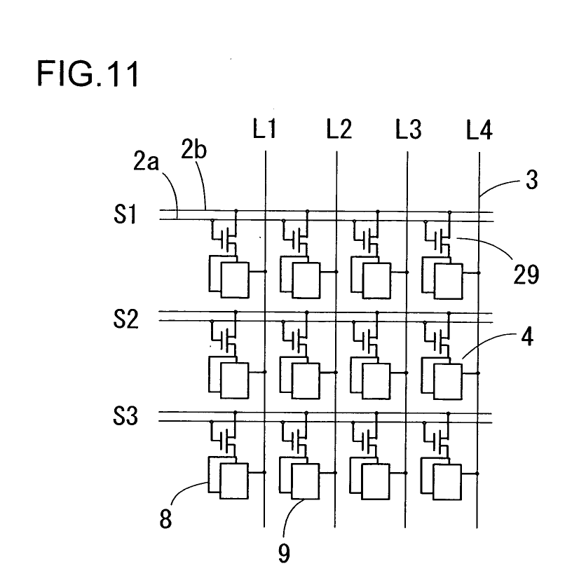

In FIG. 11, there is shown a schematic view showing a pressure detection region in a case where the TFTs 29 are provided as switching elements. The pressure detection region of FIG. 11 is different from that of FIG. 10 in that the gate electrodes of TFTs 29 are connected to one of first wires 2 in pair and the source electrodes thereof are connected to the other first wire 2. The gate electrodes of the TFTs 29 are connected to a first wire 2a for gate electrodes and the source electrodes of the TFTs 29 are connected to a first wire 2b for source electrodes. The drain electrodes of the TFTs 29 are connected to the respective corresponding first electrodes 8. In FIG. 11, TFTs 29 connected to the first wire 2a are turned on or off by the presence/absence of a signal on the first wire 2a, and the signal from the first wire 2b is supplied to a first electrode 8 by the TFT 29 having turned on. The TFT 29 having turned off can prevent it from occurring, as done in the construction of FIG. 10, that a signal flowing in a second wire 3 is, by being transmitted to a second electrode 9 and a first electrode 8 in a sensor section 4 if the case actually occurs, transmitted to the first line 2 from the first electrode 8.

Note that a construction may also be adopted in which first wires 2b for source electrodes are short-circuited at ends thereof to thereby supply a common signal onto all of the first wires 2b. With such a construction adopted, consumed power can be suppressed as compared with the construction shown in FIG. 10. While in FIG. 11, a first wire 2a for gate electrodes and a first wire 2b for source electrodes are paired and the pairs are disposed in parallel to one another, the two kinds of first wires 2 are superimposed one on the other by being provided on respective both sides of an insulating film made of SiNx, for example; thereby, also enabling reduction in resolution to be suppressed. While in FIG. 11, a first wire 2a for gate electrodes and a first wire 2b for source electrodes in pair are formed in the same direction as each other, one of the first wires may also be formed in the same direction as second electrodes. That is, one of the first wires 2a and 2b in pair supplying a signal to first electrodes 8 is only required to intersect with the second wires 3.

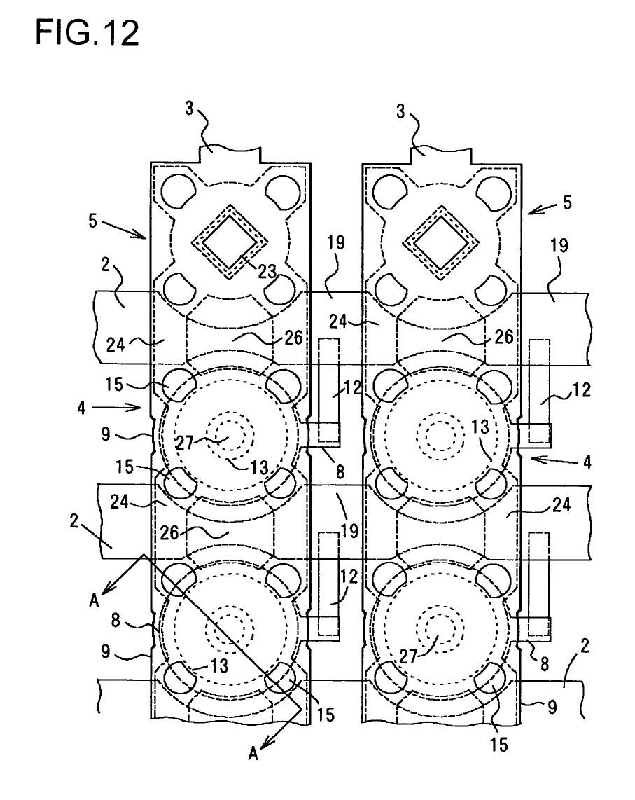

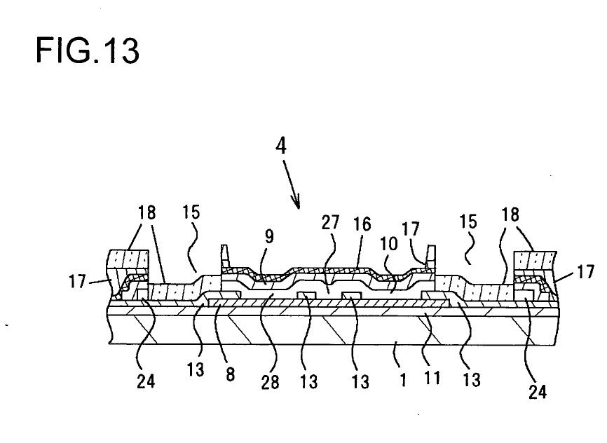

Then, description will be given of a fourth embodiment of the present invention with reference to the accompanying drawings. FIG. 12 is a plan view of four (2×2) sensor sections 4 in FIG. 1, and FIG. 13 is a sectional view (corresponding to one sensor section only) taken along line A-A line of FIG. 10. A construction of a glass electrode 1, a lower-layer insulating film 11 and first wires 2 is the same as that of the first embodiment; therefore, description thereof will not be repeated herein.

A numerical symbol 8 is a first electrode disposed on a substrate 1, and the first electrode 8 has a disk-like land of which a central portion is a contact point. Each of the first electrodes 8 is, for example, of a layer structure made of Al and Mo, and the first electrodes 8 are connected to the first wire 2 disposed in one row direction through the respective contact layers 12. Each of the contact layers 12 is of the same construction as the first embodiment; therefore, description thereof will not be repeated herein.

The first wire 2 has larger width portions 19 in respective spaces between adjacent sensor sections 4 in the one row direction, while having narrower portions in the vicinity of the sensor section 4 in a column direction. A contact layer 12 connected to the corresponding larger width portion 19 serves as a connection element connecting between the first wire 2 and a first electrode 8 and requires a predetermined length as shown in the figure, which necessitates it that the larger width portion 19 of the first wire 2 swells out on the side of the first wire 2 to which the contact layer 12 is not connected. By providing such a larger width portion 19 to each pressure sensor section 4, a resistance value of a first wire 2 is reduced despite the presence of narrower portions 26, which has a little a smaller width, on the whole and further secure adherence of the first wire 2 so as to be harder to be separated.

In this embodiment, a shape of the narrower portion 26 of the first wire 2 is in conformity with the outline of the first electrode 8 abutting thereon. That is, the outline of the first electrode 8 is almost circular, the corresponding narrower portion 26 has an outline at an almost constant spacing from the outline of the sensor section 4 and the outline of the narrower portion 26 follows the outline of the first electrode 8 so as to be in the shape of almost an arc. Since a narrower portion 26 can be provided in the vicinity of the corresponding sensor section 4, a packing density of sensor sections 4 in integration can be higher and an area at a site of which a sensor section 4 receives a pressure can be larger, thereby enabling a pressurized position to be detected at a higher resolution with good sensitivity. Such an effect can be ensured with better efficiency by adopting a shape of the narrower portion 26 in conformity with the outline of the first electrode 8 abutting thereon.

A numerical symbol 9 indicates a second electrode disposed opposite to the first electrode 8 with a cavity 10 interposed therebetween and works additionally as a second wire 3 in one column direction. The cavities 10 between the first electrodes 8 and the second electrodes 9 in the respective sensor sections 4 communicate with each other in each column direction through two communication paths 24 between adjacent sensor sections 4 and are opened in the vent hole 5 disposed at one end of the column. The second electrodes 9 is made of, for example, Mo and the periphery thereof is sufficiently remote from the outline of the first electrode 8 and release holes 15 are provided at the four corners thereof. In this example of the figure, the second electrode 9 substantially determines a size of the sensor section 4 and the size is, for example, of the maximum diameter of 50 μm for each contact point sensor (or a tetragon with a side of 50 μm).

A numerical symbol 13 indicates a first insulating film stacked on a first electrode and in the shape of two rings disposed concentrically. The first insulating film 13 is made of, for example, SiNx or SiO₂ and covers main portions of the lower-insulating film 11 and the first electrode 8. Since the central portion of the first electrode 8 is a contact point region 27 functioning as a contact point, the central portion of the electrode is exposed without being covered with the first insulating film 13.

The release holes 15 are holes for forming a cavity 10 by removing an intermediate layer 25 as described above and are located in communication paths 24. The release holes 15 are provided in the second electrode 9 in a case where the second electrode 9 covers the entire upper side of the cavity 10, while a construction is allowed in which a film used for forming through holes is separately provided and the release holes 15 are formed in the film. The plural release holes 15 are preferably provided to one sensor section and further a set of the plural release holes 15 is preferably provided to each sensor section. Since the release holes 15 are desirably closed with an insulating film 18 or the like at the final stage, the first electrode 8 cannot be observed from the release holes 15 in an operating state of the sensor section 4 even if the release holes 15 are positioned above the first electrode 8. This is because since the release holes 15 are located near the contact point region 27, there arises a possibility of dust or liquid intruding into the cavity 10 to cause a trouble such as contact fault or the like if the release holes are open in the outside air.

A numerical symbol 16 indicates a second insulating film, and the second insulating film 16 may work simply so as to prevent the second electrodes 9 from being exposed to the outside air, or may further work so as to reinforce or support the second electrodes 9. By providing the second insulating film 16 on the surface of the second electrodes 9, water can be prevented from penetrating through the second electrodes 9 to intrude into the cavity 10 after the cavities 10 is formed, thereby enabling a product yield to be increased. Numerical symbols 17 and 18 indicate insulating films required for a reason or reasons associated with the process, or for adjusting a stress imposed thereto.

While the second electrode 9 itself has an almost uniform thickness, the second electrode 9 assumes a wavy profile with depression and protrusion combined since the surface of the intermediate 25 has a profile of depression and protrusion combined in accordance with the shape of the first insulating film 13. That is, a site where the first insulating film 13 exists is protruded, while a site where the recess 28 exists is depressed and the pattern in the plan view thereof, if a protrusion and a depression are formed concentrically, looks like wave rings when a stone is thrown onto a water surface. Since the first wire 2 is narrowed in the vicinity of the sensor section 4, the second electrode 9 can secure a larger area as a pressure detection section, is flexible and has an increased restoring force since the second electrode 9 has a profile with depression and protrusion combined on the whole. Even when a strong pressure is applied to the second electrode 9 and the second insulating film 16 stacked thereon, a stress is distributed in the whole of the second electrode 9 and the second insulating film 16, which increases a strength to render breakage of the second electrode 9 very rare. Note that the fabrication method for the sensor sections 4 and vent hole sections 5 of the embodiment is the same as that of the first embodiment; therefore, description thereof will not be repeated herein.

While in this embodiment, description is given of the case where the shape of the first electrode 8 has a land portion, that is a disk, no specific limitation is imposed on a shape so as to have a central circular portion and an annular portion combined. In a case where each second electrode 9 is preferably formed so as not to be of a wavy profile, the first insulating film 13 has only to be thin and flat.

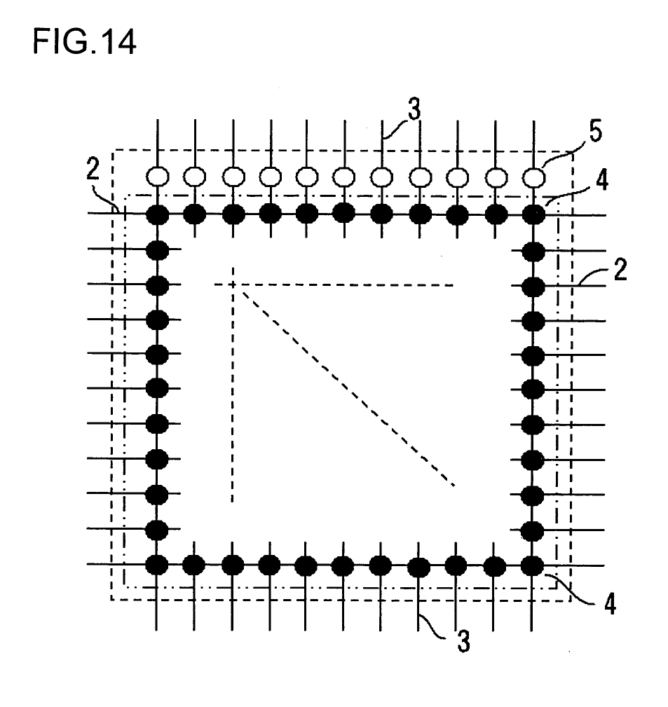

Then, description will be given of an arrangement method for sensor sections, vent hole sections and wires with which a high precision pressure sensor is realized with decrease in erroneous detection. FIG. 14 is a schematic view of a pressure sensor according to a fifth embodiment of the present invention. A construction of the pressure sensor is the same as that of the first embodiment; therefore, description thereof will not be repeated herein. In FIG. 14, a portion indicated with two dot chain lines is the outermost peripheral boundary portion where the sensor sections 4 along the outermost periphery are exists.

The outermost peripheral boundary portion in a case where the vent hole sections 5 are provided is indicated inside the portion indicated with a dotted line. That is, in a case where the vent hole sections 5 are provided, a dotted line is a boundary inside which the vent hole sections 5 exist or in areas where the vent hole sections 5 does not exist, the dotted lines are a boundary inside which the outermost sensor sections 4 exist. Note that in FIG. 14, the two dot chain lines and the dotted lines are drawn as boundaries larger in area enclosed thereby than those where the outermost sensor sections 4 and the vent hole sections 5, respectively, actually exist. Moreover, the two dot chain lines and the dotted lines are drawn slightly apart from the boundary where the sensor sections 4 along the outermost periphery exists. The first wires 2 and the second wires 3 all extend outwardly from the outermost peripheral boundary portion along all the sides, including sides on which neither the scanning circuit 6 nor the sensing circuit 7 exist, by 100 μm or more.

If the ends of the first wires 2 and the second wires 3 are located in the vicinity of the outermost peripheral boundary portion outwardly by the order in the range of several μm to 10 μm, a thickness of the sensor section 4 in the vicinity thereof is easy to be non-uniform, which results in differences among sensitivities of the sensor sections. Moreover, a difference in sensitivity occurs between sensor sections in the central portion and those in the peripheral portion, which increases a proportion of results of erroneous detection, which provides a pressure sensor with poor precision. In a case where all of the first wires 2 and all of the second wires 3 further extend from the outermost peripheral boundary portion, the thickness of the sensor section 4 is more uniform in the vicinity of the outermost peripheral boundary portion, and the thickness of the sensor section 4 in the central portion and the thickness of the sensor section 4 along the peripheral portion are more uniform over the two groups; therefore enabling a high precision pressure sensor less in erroneous detection to be realized.

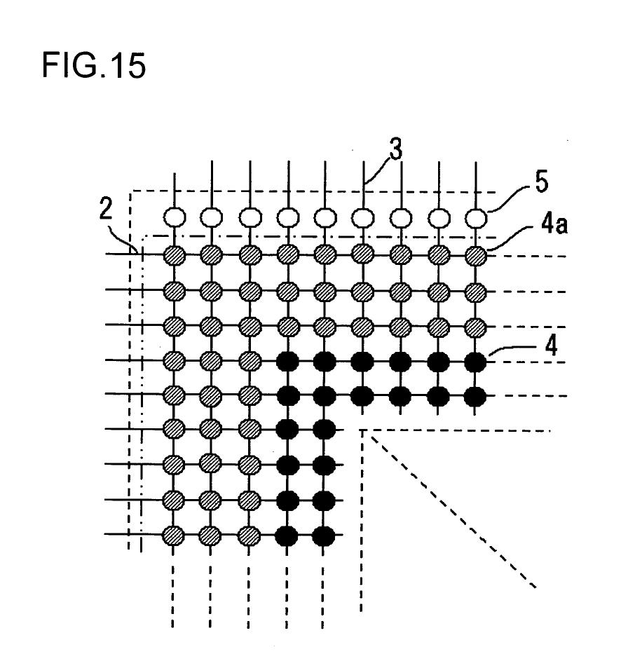

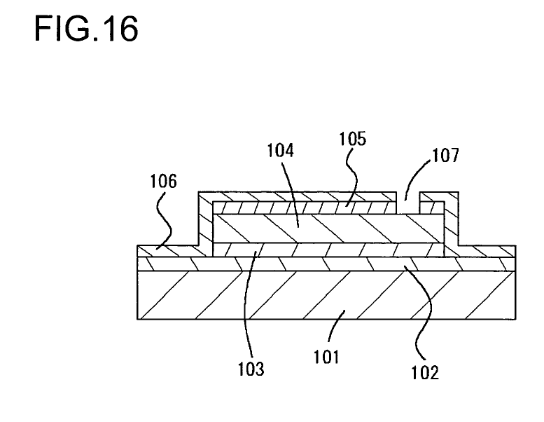

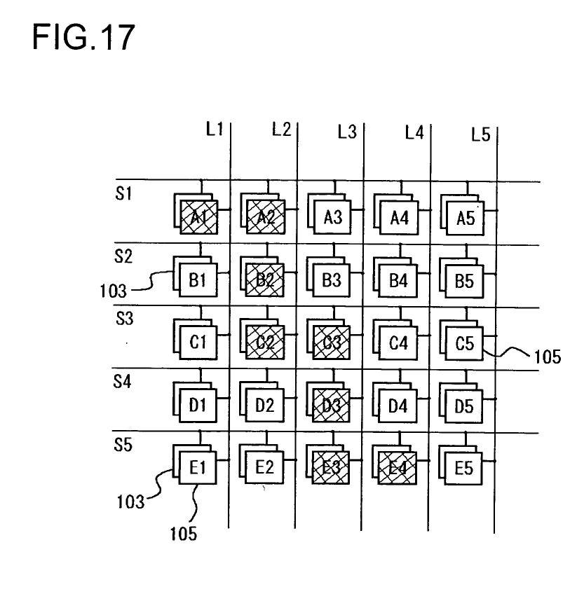

FIG. 15 is a schematic view showing a part of the pressure detection region of a pressure sensor according to a sixth embodiment of the present invention. A construction of the pressure sensor is the same as that of the first embodiment; therefore, description thereof will not be repeated herein. In FIG. 15, sensor sections 4 on the outermost three rows and columns are used as dummies 4a having no detection function for a shape.

Even in a case where the first wires 2 and the second wires 3 extend outwardly from a region including the sensor sections 4 and the vent hole sections 5, difficulty is encountered in rendering a thickness in the peripheral portion and a thickness in the central portion perfectly uniform over both portions in a film formation step of a fabrication process for a pressure sensor; therefore, sensitivities of the sensor sections located in the vicinity of the outermost periphery easily differ among themselves to render the sensor sections on the whole non-uniform in sensitivity, resulting in a pressure sensor poor in precision. By fabricating the sensor sections 4 in the vicinity of the outermost periphery that have a possibility of producing such a problem as the dummies 4a, the sensor sections 4 inside the dummies 4a have a very uniform sensitivity; thereby enabling a high precision pressure sensor less in erroneous detection on the whole to be realized. Note that while in this embodiment, the sensor sections on the outermost three columns and three rows are used as dummies 4a, a range in which sensor sections serving as dummies are disposed can be arbitrarily set and the scope may be either only the outermost one column and one row of the pressure detection region or the outermost two columns and two rows.

While in the present invention, description is given of the pressure sensor detecting a shape based on the presence and absence of contact between electrodes of a pair in each sensor section 4, the present invention is effective for a pressure sensor of any type having cavities in the sensor sections and can be applied to, for example, an electrostatic capacity type sensor.

### INDUSTRIAL APPLICABILITY

In the present invention, a pressure sensor in which plural microsensor sections are arranged in a matrix has wires disposed around each sensor section according to integrated arrangement of the sensor sections, wherein a shape and configuration of the wires are in conformity with those of the sensor sections. With such a construction adopted, a packing density of the sensor sections in integration is increased to thereby increase a proportion in area occupied by the sensor sections, thereby enabling a pressure sensor with improved resolution to be provided.

In a case where the ends of wires are located in the vicinity of the outermost peripheral boundary portion where the sensor sections along the outermost periphery exist, a sensitivity of the sensor section is easy to be non-uniform, while by further extending the wires longer outwardly from positions in the vicinity of the outermost peripheral boundary portion, a sensitivity of the sensor can be more unifomm, thereby enabling a high precision sensor to be provided.

By disposing dummy sensor sections in the outermost peripheral portion of a region including the sensor sections, only the sensor sections where a sensitivity is uniform can be used for pressure detection, thereby enabling a higher precision sensor to be realized.

By connecting a first wire to first electrodes by contact layers with a resistance value higher than the first wire, a current can be determined whether or not the current has flowed in another sensor section by detecting the current value flowing a second wire, thereby enabling a precision of the sensor itself to be improved.

By forming a contact layer with polycrystalline silicon or an amorphous silicon layer mixed with a conductive impurity, a pattern can be formed using optical means. In a case where the contact layer is made of n⁺a-Si, a packing density of sensor sections in integration is raised since the contact layer can be shorter than in a case of polycrystalline silicon layer, thereby enabling resolution to be improved.

While a signal flowing in a second wire flows into another first wire through another microsensor section on which no scanning signal is supplied and thereby erroneous detection has been encountered, a high precision sensor preventing erroneous detection can be obtained by forming contact layers with switching elements such as a thin film transistor.

1. A pressure sensor comprising: plural first wires and plural second wires intersecting with each other in arrangement; and sensor sections provided in the vicinities of the respective corresponding intersections, wherein
each of the sensor sections includes:
a first electrode electrically connected to the first wire;
a second electrode disposed opposite to the first electrode; and
a cavity formed between the first electrode and the second electrode, and
the second wires work additionally as the second electrodes in the sensor sections.

2. The pressure sensor according to claim 1 wherein
the first wires have larger width portions in respective spaces between adjacent sensor sections.

3. (canceled)

4. The pressure sensor according to claim 2 or 3, wherein
the first wires are connected to the first electrodes at the larger width portions.

5. The pressure sensor according to claim 1, wherein
all of the first wires and all of the second wires extend outwardly from the outermost peripheral boundary portion where sensor sections along the outermost periphery are disposed.

6. The pressure sensor according to claim 5, wherein
all of the first wires and all of the second wires extend outwardly from the outermost peripheral boundary portion by a length of 100 μm or more.

7. The pressure sensor according to claim 1, wherein
dummy sensor sections are disposed in the outermost peripheral portion of a region including the sensor sections.

8. The pressure sensor according to claim 1, wherein
the first wires are connected to the first electrodes through contact layers higher in resistance than the first wires.

9. The pressure sensor according to claim 8, wherein
the contact layers are formed with a silicon layer mixed with a conductive impurity.

10. The pressure sensor according to claim 8, wherein
the contact layers are formed with polycrystalline silicon.

11. The pressure sensor according to claim 1, wherein
the first wires are connected to the first electrodes through switching elements.

12. The pressure sensor according to claim 11, wherein
the switching elements are thin film transistors.

13. The pressure sensor according to claim 1, wherein
a scanning signal is sequentially supplied onto the plural first wires.
